(19) United States
(12) Patent Application Publication
(10) Pub. No.: US 2023/0058552 A1
(43) Pub. Date: Feb. 23, 2023

(54) COLLISION PREVENTION SYSTEM AND COLLISION PREVENTION METHOD OF AUTOMATED OVERHEAD HOIST

(71) Applicant: CHANGXIN MEMORY TECHNOLOGIES, INC., Hefei City, Anhui (CN)

(72) Inventor: ShanShan Zheng, Hefei City, Anhui (CN)

(21) Appl. No.: 17/433,022

(22) PCT Filed: Mar. 10, 2021
(86) PCT No.: PCT/CN2021/079877

§ 371 Date: Aug. 23, 2021

(30) Foreign Application Priority Data
Mar. 10, 2020 (CN) 202010160868.3

(51) Int. Cl. B66C 15/04; B66C 13/44; H01L 21/677

(52) U.S. Cl. CPC B66C 15/045; B66C 13/44; H01L 21/67733; H01L 21/6773

(57) ABSTRACT

The present application discloses a collision prevention system of automated overhead hoist, including: a traveling track; overhead hoists movably mounted on the traveling track; photoelectric sensing apparatuses, arranged below the traveling track, and configured to form protection areas below the traveling track and output a feedback signal when detecting that an unexpected object enters the protection areas; and a control system, connected to the overhead hoists and the photoelectric sensing apparatuses, and configured to control at least one of the overhead hoists to stop moving upon receiving the feedback signal.

### CROSS-REFERENCE TO RELATED APPLICATIONS

The present application claims the priority to Chinese Patent Application 202010160868.3, titled “Collision prevention system and collision prevention method of automated overhead hoist”, filed on Mar. 10, 2020, which is incorporated herein by reference in its entirety.

### TECHNICAL FIELD

The present application relates to the technical field of automated material handling system (AMHS) in semiconductor integrated circuits, and in particular to collision prevention system and collision prevention method of automated overhead hoist.

### BACKGROUND

The automated material handling system (AMHS) in semiconductor integrated circuits is used to carry a batch of semiconductor products and transfer them between various operating devices or storage cabinets, thereby avoiding the inefficiency of traditional manual handling and ensuring the cleanliness of the production plants. Therefore, the automated material handling system has become one of the necessary devices in the semiconductor manufacturing plants.

The core carrier in the automated material handling system is overhead hoist transfer (OHT), and the overhead hoist devices are often used to transport unified pods where the wafers are placed.

### SUMMARY

An aspect of the present application provides a collision prevention system of automated overhead hoist, comprising:

a traveling track;

overhead hoists movably mounted on the traveling track;

photoelectric sensing apparatuses, arranged below the traveling track, and configured to form protection areas below the traveling track and output a feedback signal when detecting that an unexpected object enters the protection areas; and

a control system, connected to the overhead hoists and the photoelectric sensing apparatuses, and configured to control at least one of the overhead hoists to stop moving upon receiving the feedback signal.

Another aspect of the present application provides a collision prevention method of automated overhead hoist, comprising:

during the movement of overhead hoists along a travelling track, forming a feedback signal when detecting that an unexpected object enters protection areas formed by photoelectric sensing apparatuses; and

controlling at least one of the overhead hoists to stop moving based on the feedback signal.

### BRIEF DESCRIPTION OF THE DRAWINGS

In order to better describe and illustrate the embodiments of the present application, reference may be made to one or more drawings. However, the additional details or examples used to describe the drawings should not be considered as any limitation to the concept of the present application or any one of the currently described embodiments or preferred implementations.

FIG. 1 is an overall structure diagram of a collision prevention system of automated overhead hoist according to the present application;

FIG. 2 is an overall structure diagram of a photoelectric sensing apparatus in the collision prevention system of automated overhead hoist according to an embodiment of the present application;

FIG. 3 is an overall structure diagram of a collision prevention system of automated overhead hoist according to an embodiment of the present application;

FIG. 4 is an overall structure diagram of a collision prevention system of automated overhead hoist according to another embodiment of the present application; and

FIG. 5 is a flowchart of a collision prevention method of automated overhead hoist according to the present application.

### DETAILED DESCRIPTION

The automated overhead hoist has a high traveling speed when it is working. For example, the maximum speed of the automated overhead hoist for travelling on a straight road is 300 m/min When the automated overhead hoist is traveling at a high speed, if a person or an object suddenly appears in front of the automated overhead hoist, the person may be injured or the automated overhead hoist may be damaged.

At present, there are two solutions to solve this problem.

1. A protective net may be installed on the track at positions without machines (the protective net cannot be installed at positions with machines since it will affect the loading/unloading of the machines). This can provide the collision prevention effect. However, it is difficult to make a determination as to which height the protective net should be installed at, on the premise of not affecting the transfer of the overhead hoists on the machines while leaving a high enough space for operations on the ground. Furthermore, it is inconvenient to disassemble or assemble the protective net since it is very heavy, and it is less flexible in operation. The protective net cannot be applied in large scale.

2. A height-limiting sign may be hung at the entrance to the track in each bay (procedure) to warn the operators. However, this method just plays a warning role.

In some embodiments of the present application, an overhead hoist system based on non-contact power supply using power supply lines is used. The overhead hoist system is usually installed in a clean room in a semiconductor factory and used for handling workpieces such as unified pods.

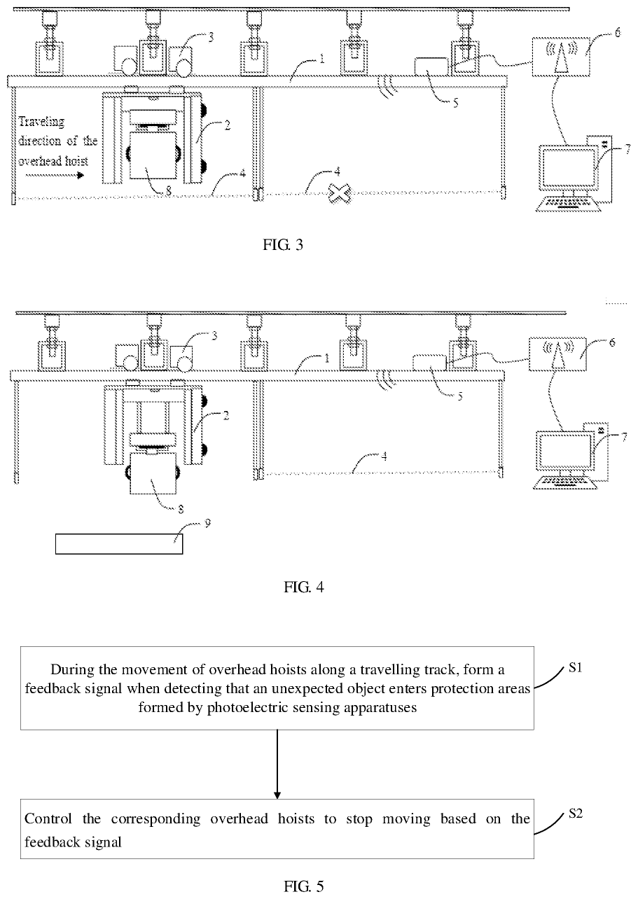

Referring to FIG. 1 and FIG. 3, in an embodiment, the present application provides a collision prevention system of automated overhead hoist, comprising: a traveling track 1, overhead hoists 2 movably mounted on the traveling track, photoelectric sensing apparatuses 4 and a control system 7;

the traveling track 1 is hung from the ceiling by a plurality of pillars;

the overhead hoists 2 are installed on the traveling track 1 through a traveling portion, and the traveling portion usually comprises guide wheels 3;

the photoelectric sensing apparatuses 4 are arranged below the traveling track 1, and configured to form protection areas below the traveling track 1 and output a feedback signal when detecting that an unexpected object enters the protection areas; in order not to affect the travelling of the overhead hoists 2, the photoelectric sensing apparatuses 4 may be hung from the traveling track 1 through pillars; and

the control system 7 is connected to the overhead hoists 2 and the photoelectric sensing apparatuses 4, and configured to control the corresponding overhead hoists 2 to stop moving upon receiving the feedback signal.

In the collision prevention system of automated overhead hoist, by installing the photoelectric sensing apparatuses 4 below the travelling track 1 of the overhead hoists 2 to detect whether an unexpected object enters the protection areas and controlling the corresponding overhead hoists 2 to stop moving by the control system 7 when detecting an unexpected object enters the protection areas, it can avoid the risk of hitting the overhead hoists by the unexpected object, thereby reducing the possible damage to the operators, the workpieces or the overhead hoists. Furthermore, this monitoring method is accurate and timely, and can effectively improve the safety of the overhead hoists, with high flexibility, high operability, and good prospects for large-scale applications.

As shown in FIG. 3, in an example, the collision prevention system of automated overhead hoist further comprises: a wireless transmission device 5, respectively connected to the photoelectric sensing apparatuses 4 and the control system 7, and configured for the wireless signal transmission between the photoelectric sensing apparatuses 4 and the control system 7. The wireless transmission device 5 may comprise, but not limited to, a wireless access point. In this way, the wireless transmission avoids complicated wiring and facilitates subsequent maintenance.

As shown in FIG. 3, in an example, multiple photoelectric sensing apparatuses 4 are sequentially arranged in the extension direction of the traveling track 1 so as to form a plurality of protective areas in the extension direction of the traveling track 1, so that the protection areas cover the entire overhead hoist system.

Preferably, the distance between two adjacent photoelectric sensing apparatuses 4 is 5 m to 8 m. An appropriate distance between adjacent photoelectric sensing apparatuses 4 can provide workers with a certain aerial operating area, while reducing the system cost without affecting the collision prevention effect. The photoelectric sensing apparatuses 4 are located below the overhead hoists 2, and the distance between the photoelectric sensing apparatus 4 and the bottom of the overhead hoists 2 is 10 cm to 15 cm, so as to provide a safe distance for the overhead hoists 2 to not touch the bottom of the workpieces when transferring them.

As shown in FIG. 4, in an example, the collision prevention system of automated overhead hoist further comprises machines 9. The traveling track 1 is located above the machines 9 to ensure that the overhead hoists 2 can transfer workpieces 8 on the machines 9. The workpiece here comprises, but is not limited to, unified pods.

In an example, the control system 7 is further configured to identify the position of the overhead hoists 2 that are transferring the unified pods on the machines 9, and shield the photoelectric sensing apparatuses 4 at the position of the overhead hoists 2 that are transferring the unified pods on the machines 9, to avoid unnecessary accidental stop of other overhead hoists 2 in work during the transfer process to thus affect the working efficiency

In an example, the control system 7 is configured to control, upon receiving the feedback signal, the overhead hoists 2 located above a group of protection areas ahead the photoelectric sensing apparatus 4 that detects the unexpected object to stop moving. The group ahead refers the first group ahead in the travelling direction of the overhead hoists 2.

In another example, the control system 7 is configured to control, upon receiving the feedback signal, the overhead hoists 2 above the photoelectric sensing apparatus 4 that detects the unexpected object to stop moving.

In still another example, the control system 7 is configured to control, upon receiving the feedback signal, the overhead hoists 2 above the photoelectric sensing apparatus 4 that detects the unexpected object and the overhead hoists 2 above the group of protection areas ahead to stop moving.

In yet another example, the control system 7 is configured to control, upon receiving the feedback signal, the overhead hoists 2 above the photoelectric sensing apparatus 4 that detects the unexpected object and the overhead hoists 2 above two photoelectric sensing apparatuses 4 that are adjacent to the photoelectric sensing apparatus 4 that detects the unexpected object to stop moving.

The control system 7 usually receives the operating status signals from the overhead hoists 2 through a hub, and sends control signals to the overhead hoists 2 through the hub to control the overhead hoists 2 to work or not.

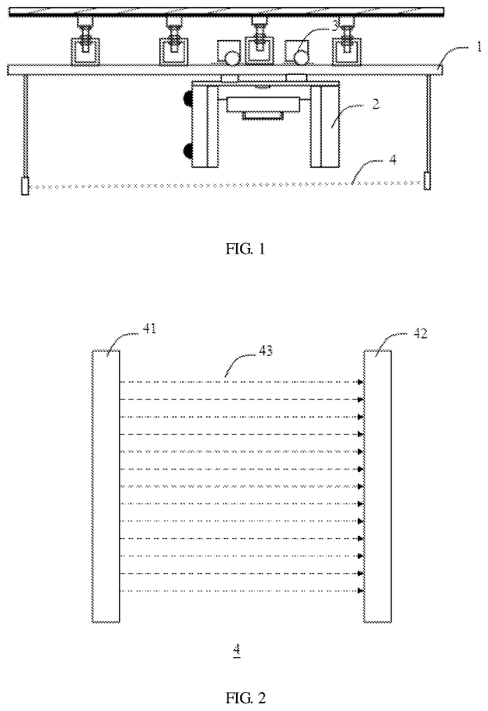

As shown in FIG. 2, the photoelectric sensing apparatus 4 usually comprises an emitting unit 41, a receiving unit 42 and a feedback unit (not shown); the emitting unit 41 and the receiving unit 42 are arranged in parallel and spaced apart in the extension direction of the travelling track 1, and the feedback unit is connected to the receiving unit 42; wherein the emitting unit 41 is configured to emit detection light 43 to form a light curtain between the emitting unit 41 and the receiving unit 42; the receiving unit 42 is configured to receive the detection light 43; and the feedback unit is configured to output the feedback signal when the light curtain is blocked by the unexpected object. For example, in an example, when the intensity of the detection light 43 received by the receiving unit 42 is less than the intensity of the detection light 43 emitted by the emitting unit 41, it is determined that the detection light 43 is blocked by the unexpected object. The photoelectric sensing apparatus 4 comprises, but is not limited to, a photoelectric protection device (light curtain). When a photoelectric protection device is used, the working principle is that the emitting unit 41 comprises a plurality of infrared emitting diodes, and the receiving unit 42 comprises the same number of infrared receiving diodes as the infrared emitting diodes. When there is no obstacle between the infrared emitting diodes and the infrared receiving diodes on the same straight line, the modulation signals (light signals) emitted by the infrared emitting diodes arrive at the infrared receiving diodes smoothly. After the infrared receiving diodes receive the modulation signals, the output of the corresponding internal circuit is at low level. When there is an obstacle between the infrared emitting diodes and the infrared receiving diodes on the same straight line, the modulation signals (light signals) emitted by the infrared emitting diodes cannot arrive at the infrared receiving diodes smoothly. In this case, the infrared receiving diodes cannot receive the modulation signals, and the output of the corresponding internal circuit is at high level. When no object passes through the light curtain, the modulation signals (light signals) emitted by all the infrared emitting diodes can smoothly arrive at the corresponding infrared receiving diodes on the other side, so that the output of all the internal circuits is at low level. In this way, the presence or absence of an object can be determined by the analysis of the status of the internal circuits.

As shown in FIG. 5, the present application further provides a collision prevention method of automated overhead hoist, comprising:

S1: during the movement of overhead hoists 2 along a travelling track 1, forming a feedback signal when detecting that an unexpected object enters protection areas formed by photoelectric sensing apparatuses 4; and

S2: controlling at least one of the overhead hoists to stop moving based on the feedback signal.

In an example, after S2, the collision prevention method of automated overhead hoist further comprises:

S3: controlling the overhead hoists, which are stopped, to continue working, when detecting that the unexpected object exits the protection areas formed by the photoelectric sensing apparatuses 4.

In another example, the collision prevention method of automated overhead hoist further comprises:

During the movement of the overhead hoists 3 along the travelling track 2, the position of the overhead hoists 2 that are transferring the unified pods on the machines 9 is automatically identified, and the photoelectric sensing apparatuses 4 at the position of the overhead hoists 2 that are transferring the unified pods on the machines 9 are shielded.

In another example, the collision prevention method of automated overhead hoist further comprises:

If there are multiple protection areas, when detecting that an unexpected object enters the protection areas formed by the photoelectric sensing apparatuses 4, controlling the overhead hoists 2 located above a group of protection areas ahead the photoelectric sensing apparatus 4 that detects the unexpected object to stop moving.

Various technical features of the above embodiments can be arbitrarily combined. For simplicity, all possible combinations of various technical features of the above embodiments are not described. However, all those technical features shall be included in the protection scope of the present application if not conflict.

The embodiments described above are merely some implementations of the present application. Although those embodiments have been described in specific details, they are not construed as any limitation to the scope of the present application. It should be noted that, for a person of ordinary skill in the art, a number of variations and improvements may be made without departing from the concept of the present application, and those variations and improvements should be regarded as falling into the protection scope of the present application. Therefore, the protection scope of the present application should be subject to the appended claims.

1. A collision prevention system of automated overhead hoist, comprising:
a traveling track;
overhead hoists movably mounted on the traveling track;
photoelectric sensing apparatuses, arranged below the traveling track, and configured to form protection areas below the traveling track and output a feedback signal when detecting that an unexpected object enters the protection areas; and
a control system, connected to the overhead hoists and the photoelectric sensing apparatuses, and configured to control at least one of the overhead hoists to stop moving upon receiving the feedback signal.

2. The collision prevention system of automated overhead hoist according to claim 1, further comprising:
a wireless transmission device, respectively connected to the photoelectric sensing apparatuses and the control system, and configured for wireless signal transmission between the photoelectric sensing apparatuses and the control system.

3. The collision prevention system of automated overhead hoist according to claim 1, wherein
a plurality of photoelectric sensing apparatuses are sequentially arranged in the extension direction of the traveling track to form a plurality of protection areas in the extension direction of the traveling track.

4. The collision prevention system of automated overhead hoist according to claim 3, wherein
the distance between two adjacent photoelectric sensing apparatuses is 5 m to 8 m; and
the photoelectric sensing apparatuses are located below the overhead hoists, and the distance between the photoelectric sensing apparatuses and the bottom of the overhead hoists is 10 cm to 15 cm.

5. The collision prevention system of automated overhead hoist according to claim 3, wherein
the collision prevention system of automated overhead hoist further comprises machines, and the travelling track is located above the machines to ensure that the overhead hoists can transfer workpieces on the machines; and
the control system is further configured to identify the position of the overhead hoists transferring the workpieces on the machines, and shield the photoelectric sensing apparatuses at the position of the overhead hoists transferring the workpieces on the machines.

6. The collision prevention system of automated overhead hoist according to claim 3, wherein
the control system is configured to control, upon receiving the feedback signal, the overhead hoists located above a group of protection areas ahead the photoelectric sensing apparatus that detects the unexpected object to stop moving.

7. The collision prevention system of automated overhead hoist according to claim 1, wherein
the photoelectric sensing apparatus comprises an emitting unit, a receiving unit and a feedback unit; the emitting unit and the receiving unit are arranged in parallel and spaced apart in the extension direction of the travelling track, and the feedback unit is connected to the receiving unit; wherein
the emitting unit is configured to emit detection light to form a light curtain between the emitting unit and the receiving unit; the receiving unit is configured to receive the detection light; and the feedback unit is configured to output the feedback signal when the light curtain is blocked by the unexpected object.

8. A collision prevention method of automated overhead hoist, comprising:
during the movement of overhead hoists along a travelling track, forming a feedback signal when detecting that an unexpected object enters protection areas; and
controlling at least one of the overhead hoists to stop moving based on the feedback signal.

9. The collision prevention method of automated overhead hoist according to claim 8, further comprising:
providing a plurality of photoelectric sensing apparatuses that form a plurality of protection areas, and during the movement of overhead hoists along a travelling track, automatically identifying the position of the overhead hoists transferring the workpieces on machines, and shielding the photoelectric sensing apparatuses at the position of the overhead hoists transferring the workpieces on the machines.

10. The collision prevention method of automated overhead hoist according to claim 9, wherein
controlling the overhead hoists located above a group of protection areas ahead the photoelectric sensing apparatus that detects the unexpected object to stop moving, when detecting that an unexpected object enters the protection areas formed by the photoelectric sensing apparatuses.

11. The collision prevention method of automated overhead hoist according to claim 9, wherein
the distance between two adjacent photoelectric sensing apparatuses is 5 m to 8 m; and
the photoelectric sensing apparatuses are located below the overhead hoists, and the distance between the photoelectric sensing apparatuses and the bottom of the overhead hoists is 10 cm to 15 cm.

12. The collision prevention method of automated overhead hoist according to claim 8, wherein
the photoelectric sensing apparatus comprises an emitting unit, a receiving unit and a feedback unit; the emitting unit and the receiving unit are arranged in parallel and spaced apart in the extension direction of the travelling track, and the feedback unit is connected to the receiving unit; wherein
the emitting unit is configured to emit detection light to form a light curtain between the emitting unit and the receiving unit; the receiving unit is configured to receive the detection light; and the feedback unit is configured to output the feedback signal when the light curtain is blocked by the unexpected object.

13. The collision prevention method of automated overhead hoist according to claim 8, further comprising:
controlling the overhead hoists, which are stopped, to continue working, when detecting that the unexpected object exits the protection areas.
